(19) United States
(12) Patent Application Publication
(10) Pub. No.: US 2023/0116251 A1
(43) Pub. Date: Apr. 13, 2023

(54) RACETRACK MEMORY FOR ARTIFICIAL INTELLIGENCE APPLICATIONS

(71) Applicant: INTERNATIONAL BUSINESS MACHINES CORPORATION, Armonk, NY (US)

(72) Inventors: Heng Wu, Guilderland, NY (US); Alexander Reznicek, Troy, NY (US); Ruilong Xie, Niskayuna, NY (US); Julien Frougier, Albany, NY (US); Chen Zhang, Guilderland, NY (US)

(21) Appl. No.: 17/489,029

(22) Filed: Sep. 29, 2021

(51) Int. Cl. G06N 3/063

(52) U.S. Cl. CPC G06N 3/063

(57) ABSTRACT

A semiconductor structure is provided. The semiconductor device includes a magnetic layer located between a first electrode and a second electrode formed on a substrate. The semiconductor device further includes a first write element electrically coupled to the magnetic layer adjacent to the first electrode. The semiconductor device also includes a second write element electrically coupled to the magnetic layer adjacent to the second electrode. The semiconductor device additionally includes a plurality of read elements electrically coupled to the magnetic layer located between the first write element and the second write element.

### BACKGROUND

The present invention generally relates to machine learning, and more particularly to a racetrack memory for artificial intelligence applications.

Neuromorphic computing requires devices exhibiting synaptic behavior where the output signal can be incrementally controlled by the input signal (analog behavior).

Racetrack memory uses a spin-coherent electric current to move magnetic domains along magnetic material (e.g., nanoscopic wire). As current is passed through the magnetic material, the domains pass by magnetic read/write heads positioned near the magnetic material, which alter the domains to record patterns of bits.

However, conventional racetrack memories suffer from a data flow that is binary and one-directional. Accordingly, there is a need for racetrack memories with a non-binary, multi-directional data flow.

### SUMMARY

According to aspects of the present invention, a semiconductor structure is provided. The semiconductor device includes a magnetic layer located between a first electrode and a second electrode formed on a substrate. The semiconductor device further includes a first write element electrically coupled to the magnetic layer adjacent to the first electrode. The semiconductor device also includes a second write element electrically coupled to the magnetic layer adjacent to the second electrode. The semiconductor device additionally includes a plurality of read elements electrically coupled to the magnetic layer located between the first write element and the second write element.

According to other aspects of the present invention, a method is provided for forming a semiconductor structure. The method includes forming a magnetic layer on a substrate located between a first location where a first electrode is to be formed and a second location where a second electrode is to be formed. The method further includes forming a first write element electrically coupled to the magnetic layer adjacent to the first location. The method also includes forming a second write element electrically coupled to the magnetic layer adjacent to the second location. The method additionally includes forming a plurality of read elements electrically coupled to the magnetic layer located between the first write element and the second write element. The method further includes forming the first electrode at the first location and the second electrode at the second location.

According to yet other aspects of the present invention, a semiconductor structure is provided. The semiconductor structure includes an array of racetrack memories. Each of the racetrack memories includes a magnetic layer located between a first electrode and a second electrode on a substrate. Each of the racetrack memories further includes a first write element electrically coupled to the magnetic layer adjacent to the first electrode. Each of the racetrack memories also includes a second write element electrically coupled to the magnetic layer adjacent to the second electrode. Each of the racetrack memories additionally includes a plurality of read elements electrically coupled to the magnetic layer located between the first write element and the second write element.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a block diagram showing an exemplary computing device, in accordance with an embodiment of the present invention;

FIG. 2 is a block diagram showing an exemplary semiconductor structure implementing a racetrack memory, in accordance with an embodiment of the present invention;

FIG. 3 is a block diagram showing an exemplary device level architecture of the semiconductor structure 200 of FIG. 2, in accordance with an embodiment of the present invention;

FIG. 4 is a diagram showing an exemplary output state responsive to a pulse from the first electrode of FIG. 2, in accordance with an embodiment of the present invention;

FIG. 5 is a diagram showing an exemplary output state responsive to a pulse from the second electrode of FIG. 2, in accordance with an embodiment of the present invention;

FIG. 6 is a flow diagram showing an exemplary method for forming the semiconductor structure of FIG. 2, in accordance with an embodiment of the present invention;

FIG. 7 is a block diagram showing an exemplary formation of the magnetic layer of FIG. 2 deposited on a substrate, in accordance with an embodiment of the present invention;

FIG. 8 is a block diagram showing an exemplary formation of a tunnelling barrier, a magnetic reference layer, and a metal film, in accordance with an embodiment of the present invention;

FIG. 9 is a block diagram showing an exemplary formation of write elements and read elements, in accordance with an embodiment of the present invention;

FIG. 10 is a block diagram showing an exemplary formation of write elements and read elements, in accordance with an embodiment of the present invention;

FIG. 11 is a block diagram showing an exemplary deposition of an Inter-Layer Dielectric (ILD), in accordance with an embodiment of the present invention;

FIG. 12 is a block diagram showing an exemplary deposition of a lithographic mask defining side contacts, in accordance with an embodiment of the present invention;

FIG. 13 is a block diagram showing an exemplary dry etching down to the substrate at the left and right sides for the side contacts, in accordance with an embodiment of the present invention;

FIG. 14 is a block diagram showing formed side contacts, in accordance with an embodiment of the present invention; and

FIG. 15 is a block diagram showing an exemplary racetrack memory array, in accordance with an embodiment of the present invention.

### DETAILED DESCRIPTION

Embodiments of the present invention are directed to a racetrack memory for artificial intelligence applications.

Embodiments of the present invention propose a trace-track memory design which can store multiple bits within a single cell and wherein the data flow is bi-directional and symmetrical, thus being particularly suited to the requirements of artificial intelligence training and neuromorphic computing such as requiring devices to exhibit synaptic behavior where the output signal can be incrementally controlled by the input signal (analog behavior).

Embodiments of the present invention propose a new racetrack memory with multi-states. The term racetrack relates to the existence of a wire (the racetrack) along which magnetic domains are formed from which Domain Wall (DW) spin is read which is capable of representing multiple data states. Various read elements are used on the magnetic racetrack, combined with two write elements close to each of two end electrodes to enable different states for neuromorphic computing purposes. A write element magnetizes a region by generating a strong local magnetic field, and a read element detects the magnetization of the regions.

Embodiments of the present invention use two write elements to polarize the magnetic material beneath on the racetracks. Embodiments of the present invention use various read elements on the racetrack to read Domain Wall (DW) spin representing multiple states. To that end, respective current pulses from the two electrodes induce domain wall motion in a certain direction, representing a given state.

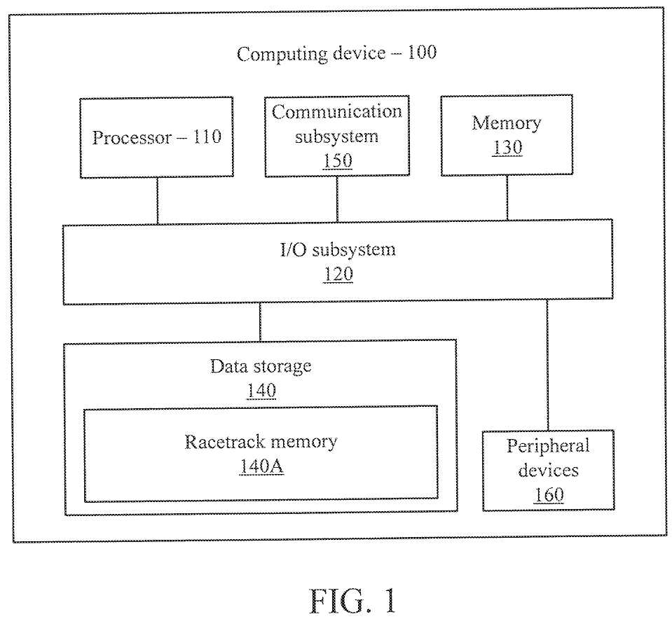

FIG. 1 is a block diagram showing an exemplary computing device 100, in accordance with an embodiment of the present invention. The computing device 100 is configured to have a racetrack memory for artificial intelligence applications.

The computing device 100 may be embodied as any type of computation or computer device capable of performing the functions described herein, including, without limitation, a computer, a server, a rack based server, a blade server, a workstation, a desktop computer, a laptop computer, a notebook computer, a tablet computer, a mobile computing device, a wearable computing device, a network appliance, a web appliance, a distributed computing system, a processor- based system, and/or a consumer electronic device. Additionally or alternatively, the computing device 100 may be embodied as a one or more compute sleds, memory sleds, or other racks, sleds, computing chassis, or other components of a physically disaggregated computing device. As shown in FIG. 1, the computing device 100 illustratively includes the processor 110, an input/output subsystem 120, a memory 130, a data storage device 140, and a communication subsystem 150, and/or other components and devices commonly found in a server or similar computing device. Of course, the computing device 100 may include other or additional components, such as those commonly found in a server computer (e.g., various input/output devices), in other embodiments. Additionally, in some embodiments, one or more of the illustrative components may be incorporated in, or otherwise form a portion of, another component. For example, the memory 130, or portions thereof, may be incorporated in the processor 110 in some embodiments.

The processor 110 may be embodied as any type of processor capable of performing the functions described herein. The processor 110 may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s).

The memory 130 may be embodied as any type of volatile or non-volatile memory or data storage capable of performing the functions described herein. In operation, the memory 130 may store various data and software used during operation of the computing device 100, such as operating systems, applications, programs, libraries, and drivers. The memory 130 is communicatively coupled to the processor 110 via the I/O subsystem 120, which may be embodied as circuitry and/or components to facilitate input/output operations with the processor 110 the memory 130, and other components of the computing device 100. For example, the I/O subsystem 120 may be embodied as, or otherwise include, memory controller hubs, input/output control hubs, platform controller hubs, integrated control circuitry, firmware devices, communication links (e.g., point-to-point links, bus links, wires, cables, light guides, printed circuit board traces, etc. ) and/or other components and subsystems to facilitate the input/output operations. In some embodiments, the I/O subsystem 120 may form a portion of a system-on-a-chip (SOC) and be incorporated, along with the processor 110, the memory 130, and other components of the computing device 100, on a single integrated circuit chip.

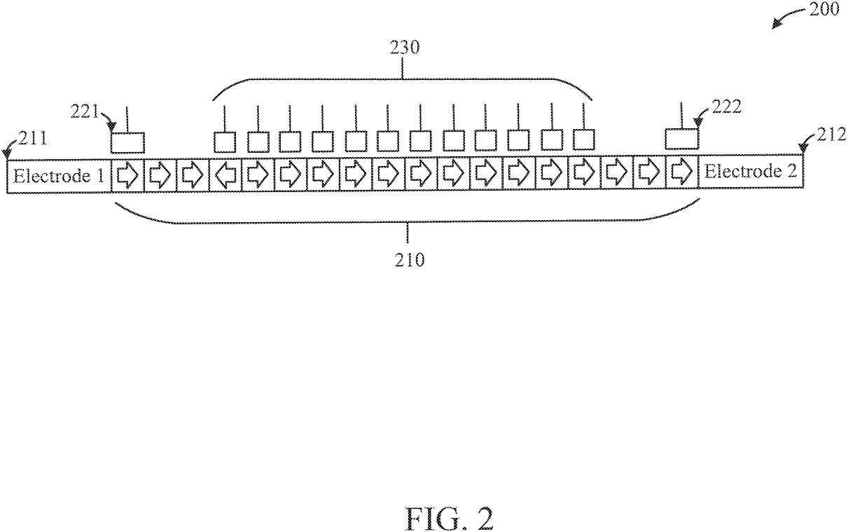

The data storage device 140 may be embodied as any type of device or devices configured for short-term or long-term storage of data such as, for example, memory devices and circuits, memory cards, hard disk drives, solid state drives, or other data storage devices. The data storage device 140 is configured as, and/or otherwise includes, a racetrack memory 140A for artificial intelligence applications. The structure of the racetrack memory is further described with respect to at least FIG. 2. Of course, the computing device 150 can include other memories in addition to the racetrack memory, while maintaining the spirit of the present invention. The communication subsystem 150 of the computing device 100 may be embodied as any network interface controller or other communication circuit, device, or collection thereof, capable of enabling communications between the computing device 100 and other remote devices over a network. The communication subsystem 150 may be configured to use any one or more communication technology (e.g., wired or wireless communications) and associated protocols (e.g., Ethernet, InfiniBand®, BluetoothⓇ, Wi-Fi®, WiMAX, etc.) to effect such communication.

As shown, the computing device 100 may also include one or more peripheral devices 160. The peripheral devices 160 may include any number of additional input/output devices, interface devices, and/or other peripheral devices. For example, in some embodiments, the peripheral devices 160 may include a display, touch screen, graphics circuitry, keyboard, mouse, speaker system, microphone, network interface, and/or other input/output devices, interface devices, and/or peripheral devices.

Of course, the computing device 100 may also include other elements (not shown), as readily contemplated by one of skill in the art, as well as omit certain elements. For example, various other input devices and/or output devices can be included in computing device 100, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized. These and other variations of the processing system 100 are readily contemplated by one of ordinary skill in the art given the teachings of the present invention provided herein.

As employed herein, the term “hardware processor subsystem” or “hardware processor” can refer to a processor, memory (including RAM, cache(s), and so forth), software (including memory management software) or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), FPGAs, and/or PLAs.

These and other variations of a hardware processor subsystem are also contemplated in accordance with embodiments of the present invention

FIG. 2 is a block diagram showing an exemplary semiconductor structure 200 implementing a racetrack memory, in accordance with an embodiment of the present invention.

The semiconductor structure 200 includes a magnetic layer 210 located between a first electrode 211 and a second electrode 212.

The semiconductor structure 200 further includes a first write element 221 electrically coupled to the magnetic layer 210 adjacent to the first electrode 211.

The semiconductor structure 200 also includes a second write element 222 electrically coupled to the magnetic layer 210 adjacent to the second electrode 212.

The semiconductor structure 200 additionally includes a plurality of read elements 230 electrically coupled to the magnetic layer 210 located between the first write element 221 and the second write element 222. In particular, each of the plurality of read elements 230 is electrically coupled to a respective one of a plurality of storage elements 240 formed by the magnetic layer 210.

The first write element 221 and the second write element 222 are configured to receive respective current pulses from the first electrode 211 and the second electrode 212 to push the domain wall motion (i.e., to polarize the magnetic material corresponding to a plurality of storage elements 240 formed by the magnetic layer 210).

The plurality of read elements 230 are configured to perform parallel reading operations to read Domain Wall (DW) spin of each of the plurality of storage elements 240, where the Domain Wall (DW) spin of each of the plurality of storage elements 240 represents a data state.

A magnetic domain is a region within a magnetic material in which the magnetization is in a uniform direction. A domain wall is an interface separating magnetic domains.

A memory cell access structure is formed by the combination of the magnetic layer 210, the first 221 and second write elements 222, the first 211 and second electrodes 212, and the plurality of read elements 230. The output of the memory cell is taken as a combination of bits output from across the plurality of read elements. A domain wall location corresponds to a change in current direction in the aligned currents in a plurality of storage elements/magnetic domains in the magnetic material that are read by the plurality of read elements. The current direction change is induced by selectively applying pulses to one or both of the first 211 and second electrodes 212 via the first 221 and second write elements 222, respectively. Multiple cells can be placed in parallel as shown herein for rapid multi-word access.

While the preceding mentions the output as words formed from bits read out from the plurality of read bits, in other embodiments, singular bit values or combinations of bit less than all in a sequence (between a first write element and a second write element) can also be ready out from selective ones of the plurality of read elements 230.

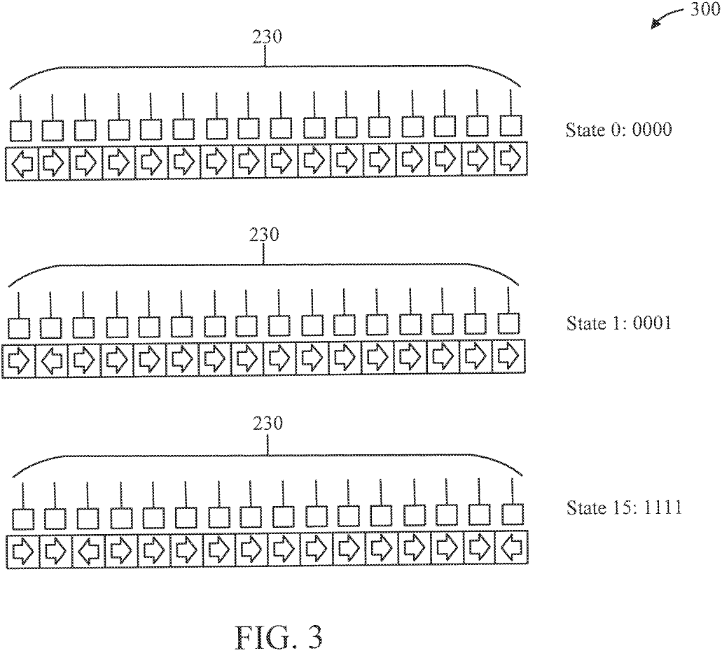

FIG. 3 is a block diagram showing an exemplary device level architecture 300 of the semiconductor structure 200 of FIG. 2, in accordance with an embodiment of the present invention.

Shown are the plurality of read elements 230 from the semiconductor structure 200 of FIG. 2, where the shown domain wall positions corresponding to the shown states. Thus, by moving the domain wall, various different states can be obtained such as state 0, state 1, and state 15 as shown, corresponding to state values of 0000, 0001, and 1111, respectively.

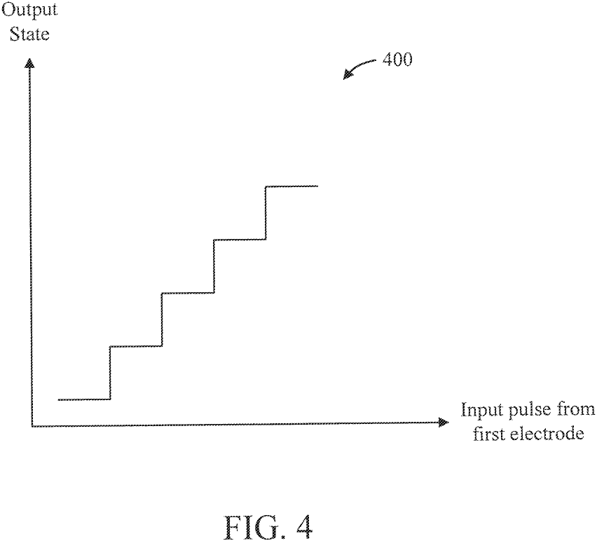

FIG. 4 is a diagram showing an exemplary output state 400 responsive to a pulse from the first electrode 211 of FIG. 2, in accordance with an embodiment of the present invention.

The output state 400 is shown relative to a plot. The x-axis of the plot corresponds to an input pulse from the first electrode 211, and the y-axis of the plot corresponds to an output state. In this case, the second electrode 212 is grounded and a pulse is input to the first electrode 211. The output state 400 is a series of increasing amplitudes.

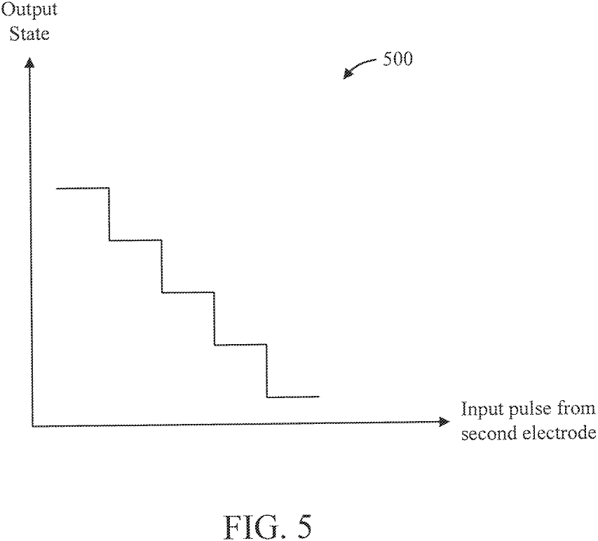

FIG. 5 is a diagram showing an exemplary output state 500 responsive to a pulse from the second electrode 212 of FIG. 2, in accordance with an embodiment of the present invention.

The output state 500 is shown relative to a plot. The x-axis of the plot corresponds to an input pulse from the second electrode 212, and the y-axis of the plot corresponds to an output state. In this case, the first electrode 211 is grounded and a pulse is input to the second electrode 212. The output state 500 is a series of decreasing amplitudes.

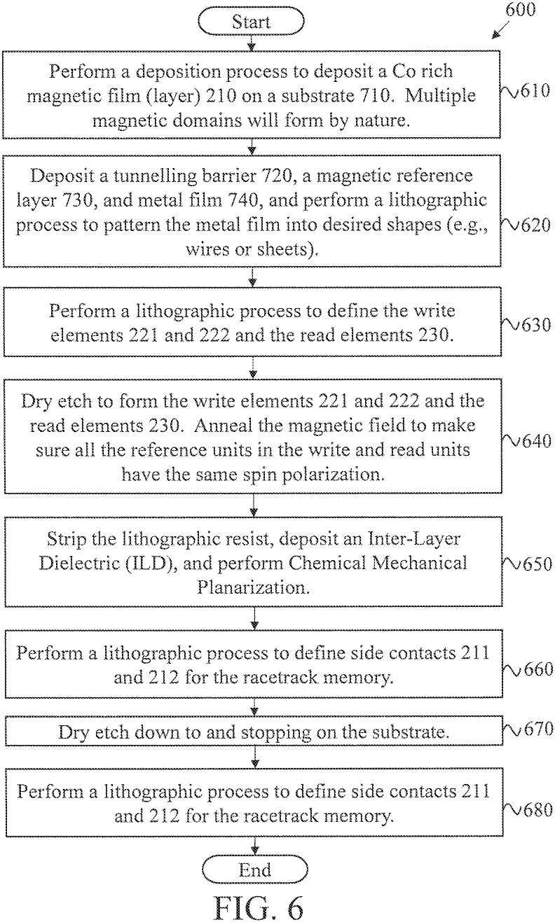

FIG. 6 is a flow diagram showing an exemplary method 600 for forming the semiconductor structure 200 of FIG. 2, in accordance with an embodiment of the present invention.

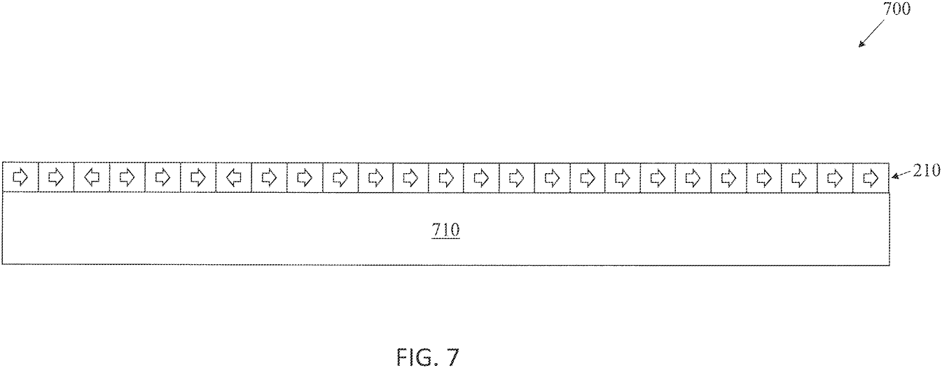

At block 610, perform a deposition process to deposit a Cobalt (Co) rich magnetic film (layer) 210 on a substrate 710. Multiple magnetic domains will form by nature. Of course other materials than Co can be used for the magnetic layer, including, for example, Manganese monoSilicide (MnSi) and so forth. The substrate can be formed from, but is not limited to, Silicon (Si), Silicon On Insulator (SOI) substrate, and so forth. FIG. 7 is a block diagram showing an exemplary formation 700 of the magnetic layer 210 of FIG. 2 deposited on a substrate, in accordance with an embodiment of the present invention.

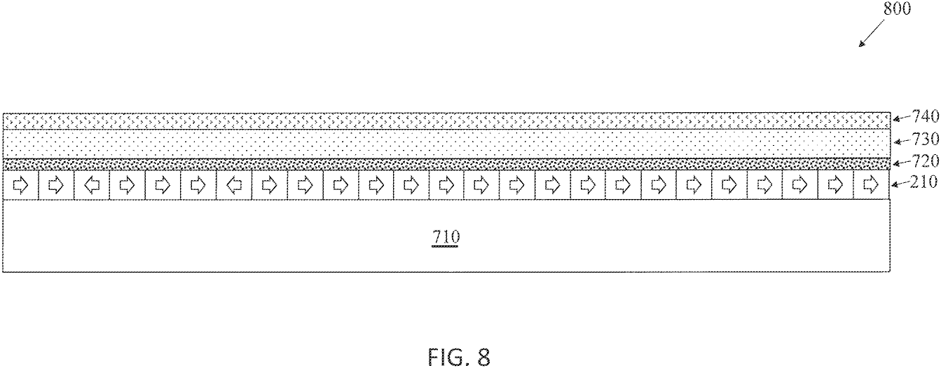

At block 620, deposit a tunnelling barrier 720, a magnetic reference layer 730, and metal film 740, and perform a lithographic process to pattern the metal film into desired shapes (e.g., wires or sheets). Atomic layer deposition, chemical layer deposition, or another deposition process can be used. The tunneling barrier 720 can be formed from, but is not limited to, Magnesium Oxide (MgO), Tantalum Oxide (TaO), Aluminum Oxide (AlO), and so forth. The magnetic reference layer 730 can be formed from, but is not limited to, Cobalt Iron (CoFe), Cobalt (Co), Iron (Fe), Cobalt Palladium (CoPd), and so forth. The metal film 740 can be formed from, but is not limited to, Tantalum Nitride (TaN), Tantalum (Ta), Titanium Nitride (TiN), Ruthenium (Ru), and so forth. FIG. 8 is a block diagram showing an exemplary formation 800 of the tunnelling barrier 720, a magnetic reference layer 730, and metal film 740, in accordance with an embodiment of the present invention.

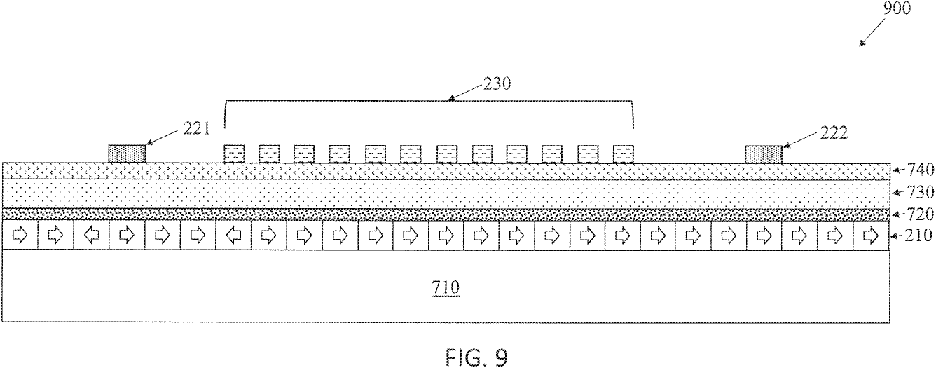

At block 630, perform a lithographic process to define the write elements 221 and 222 and the read elements 230. The write elements 221 and 222 and the read elements 230 can be formed from, but is not limited to, Tungsten (W), Copper (Cu), Tantalum (Ta), Titanium Nitride (TiN), and so forth. FIG. 9 is a block diagram showing an exemplary formation 900 of write elements 221 and 222 and read elements 230, in accordance with an embodiment of the present invention.

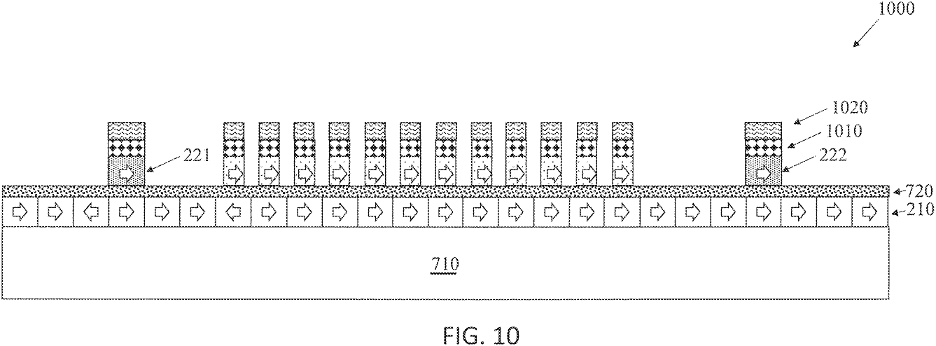

At block 640, dry etch to form the write elements 221 and 222 and the read elements 230. Anneal the magnetic field to make sure all the reference units in the write and read units have the same spin polarization. FIG. 10 is a block diagram showing an exemplary formation 1000 of write elements 221 and 222 and read elements 230, in accordance with an embodiment of the present invention. 1010 is the photoresist used in the lithographic process to define the contacts, and 1020 is the metal cap contacting the reference layer of read/write unit. The metal cap 1020 can be formed from, but is not limited to, Tantalum Nitride (TaN), Tantalum (Ta), Titanium Nitride (TiN), Ruthenium (Ru), and so forth.

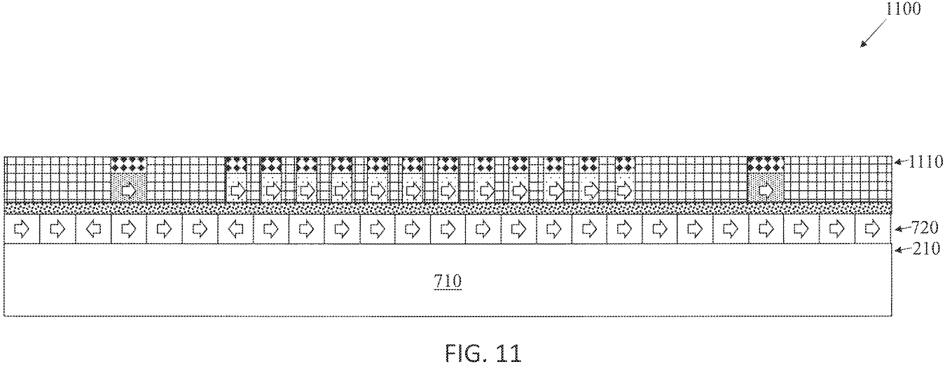

At block 650, strip the lithographic resist, deposit an Inter-Layer Dielectric (ILD) 1110, and perform Chemical Mechanical Planarization. FIG. 11 is a block diagram showing an exemplary deposition 1100 of an Inter-Layer Dielectric (ILD) 1110, in accordance with an embodiment of the present invention.

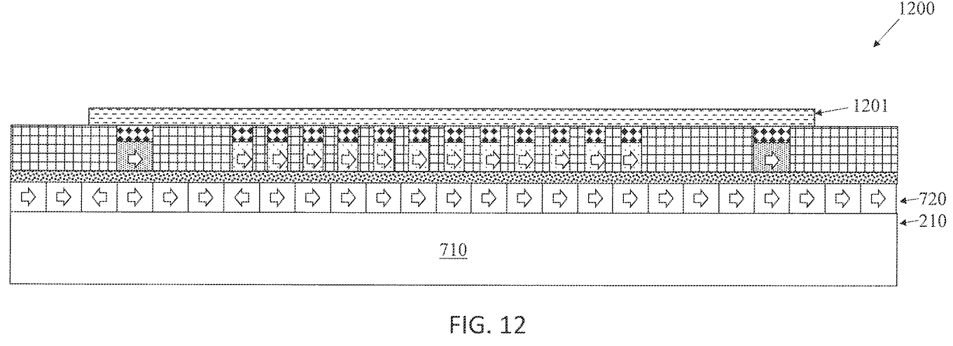

At block 660, perform a lithographic process to define side contacts 211 and 212 for the racetrack memory. FIG. 12 is a block diagram showing an exemplary deposition 1200 of a lithographic mask 1201 defining side contacts 211 and 212, in accordance with an embodiment of the present invention.

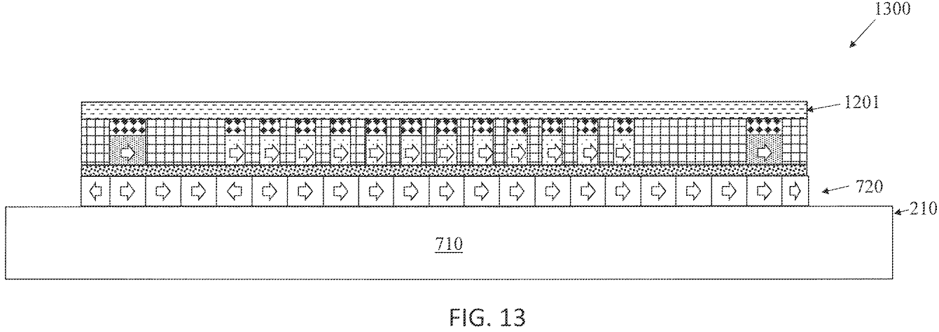

At block 670, dry etch down to and stopping on the substrate. FIG. 13 is a block diagram showing an exemplary dry etching 1300 down to the substrate 710 at the left and right sides for the side contacts 211 and 212, in accordance with an embodiment of the present invention.

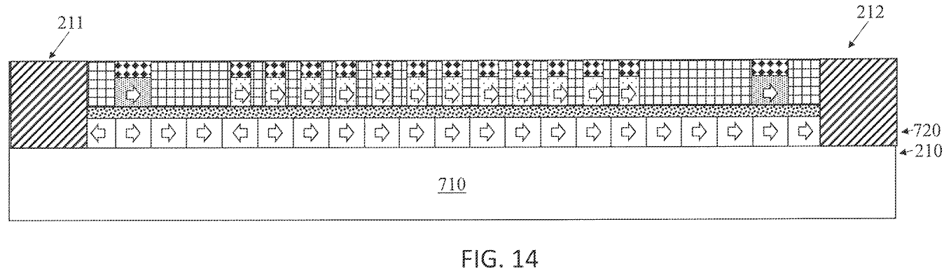

At block 680, perform a metal deposition process and a Chemical Mechanical Planarization (CMP) process to form the side contacts 211 and 212. The side contacts 211 and 212 can be formed from, but is not limited to, Tantalum Nitride (TaN), Tantalum (Ta), Titanium Nitride (TiN), Ruthenium (Ru), and so forth. FIG. 14 is a block diagram showing formed side contacts 211 and 212, in accordance with an embodiment of the present invention.

“Deposition” is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

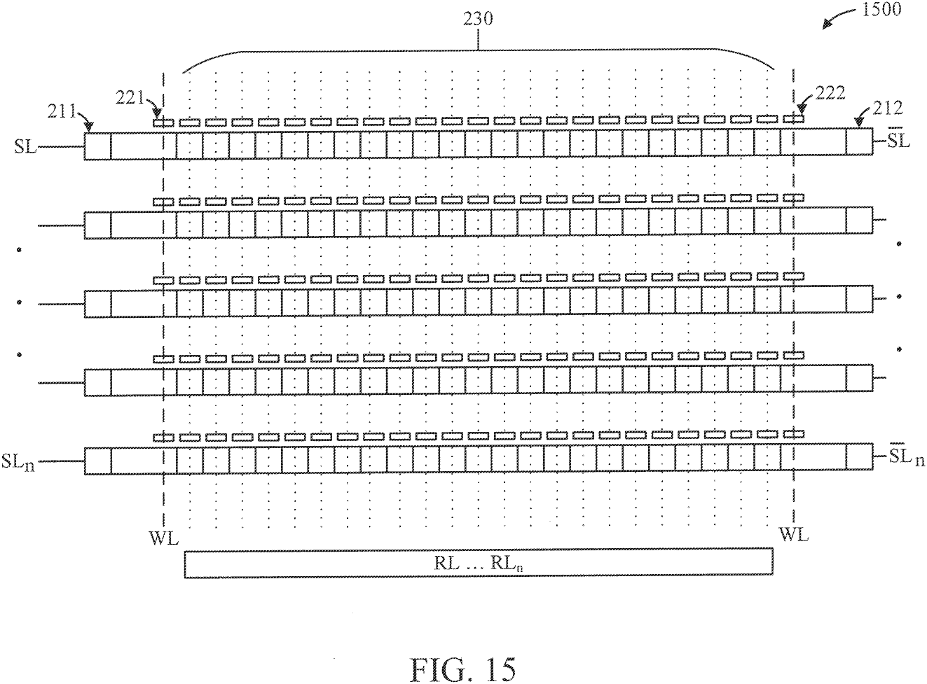

FIG. 15 is a block diagram showing an exemplary racetrack memory array 1500, in accordance with an embodiment of the present invention.

During read, for a certain racetrack: SL is float,

$$\overline{S L}$$

is grounded, current can be read from each read line, thus the state can be characterized

During write: a certain SL and

$$\overline{S L}$$

is biased, and write signal is applied on the WL. Depending on the computation needed, different write signals can be used.

An array such as that shown in FIG. 15 is readily extended into an even larger array to enable more capability, as readily appreciated by one of ordinary skill in the art, given the teachings of the present invention provided herein. To that end, an array simply to array 1500 may be extended horizontally or vertically to include multiple arrays.

The present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as SMALLTALK, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

Having described preferred embodiments of a system and method (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor structure, comprising:
a magnetic layer located between a first electrode and a second electrode formed on a substrate;
a first write element electrically coupled to the magnetic layer adjacent to the first electrode;
a second write element electrically coupled to the magnetic layer adjacent to the second electrode; and
a plurality of read elements electrically coupled to the magnetic layer located between the first write element and the second write element.

2. The semiconductor structure of claim 1, wherein the first write element and the second write element are configured to receive respective current pulses from the first electrode and the second electrode to polarize magnetic material corresponding to a plurality of storage elements formed by the magnetic layer.

3. The semiconductor structure of claim 2, wherein each of the plurality of read elements is configured to read a respective output current from a respective one of the plurality of storage elements representative of a corresponding data state.

4. The semiconductor structure of claim 1, wherein the first write element and the second write element are configured to receive respective current pulses from the first electrode and the second electrode to move a domain wall separating magnetic domains in magnetic material forming the magnetic layer in any of two opposing directions.

5. The semiconductor structure of claim 1, wherein the plurality of read elements are configured to perform parallel reading operations.

6. The semiconductor structure of claim 1, wherein each of the plurality of read elements is electrically coupled to a respective one of a plurality of storage units formed by the magnetic layer.

7. The semiconductor structure of claim 1, wherein current pulses input to the first electrode and the second electrode cause an incremental control of an output signal to be a sequence of ascending or descending values.

8. The semiconductor structure of claim 1, wherein the semiconductor structure is used in a neuromorphic computing task.

9. The semiconductor structure of claim 1, wherein the magnetic layer, the first write element, the second write element, and the plurality of read elements form a respective one of a plurality of memory cells storing a given one of a plurality of states.

10. The semiconductor structure of claim 9, wherein each of the plurality of states is independent of other ones of the plurality of states.

11. The semiconductor structure of claim 1, wherein any of the plurality of read elements is selectively activatable to read one or more bits of data.

12. The semiconductor structure of claim 1, wherein each of portions of the magnetic layer is aligned on a single plane.

13. A method for forming a semiconductor structure, comprising:
forming a magnetic layer on a substrate located between a first location where a first electrode is to be formed and a second location where a second electrode is to be formed;
forming a first write element electrically coupled to the magnetic layer adjacent to the first location;
forming a second write element electrically coupled to the magnetic layer adjacent to the second location;
forming a plurality of read elements electrically coupled to the magnetic layer located between the first write element and the second write element; and
forming the first electrode at the first location and the second electrode at the second location.

14. The method of claim 13, further comprising configuring the first write element and the second write element to receive respective current pulses from the first electrode and the second electrode to polarize magnetic material corresponding to a plurality of storage elements formed by the magnetic layer.

15. The method of claim 14, further comprising configuring each of the plurality of read elements to read a respective output current from a respective one of the plurality of storage elements representative of a corresponding data state.

16. The method of claim 13, further comprising configuring the first write element and the second write element to receive respective current pulses from the first electrode and the second electrode to move a domain wall separating magnetic domains in magnetic material forming the magnetic layer in any of two opposing directions.

17. The method of claim 13, wherein the plurality of read elements are configured to perform parallel reading operations.

18. The method of claim 13, wherein each of the plurality of read elements is electrically coupled to a respective one of a plurality of storage units formed by the magnetic layer.

19. The method of claim 13, wherein current pulses input to the first electrode and the second electrode cause an incremental control of an output signal to be a sequence of ascending or descending values.

20. A semiconductor structure, comprising:
an array of racetrack memories, each of the racetrack memories including:
a magnetic layer located between a first electrode and a second electrode on a substrate;
a first write element electrically coupled to the magnetic layer adjacent to the first electrode;
a second write element electrically coupled to the magnetic layer adjacent to the second electrode; and
a plurality of read elements electrically coupled to the magnetic layer located between the first write element and the second write element.
